(19) United States
(12) Patent Application Publication
(10) Pub. No.: US 2012/0080078 A1
(43) Pub. Date: Apr. 5, 2012

(54) PHOTOVOLTAIC MODULES AND METHODS OF MANUFACTURING

(75) Inventors: Mark Farrelly, Carlsbad, CA (US); Anand Janaswamy, Cardiff, CA (US); Shewit Agaskar, San Diego, CA (US); John Montello, San Diego, CA (US)

(73) Assignee: APPLIED SOLAR, LLC, San Diego, CA (US)

(21) Appl. No.: 12/896,843

(22) Filed: Oct. 2, 2010

(51) Int. Cl. H01L 31/048; H01L 31/02

(52) U.S. Cl. 136/251; 438/66; 257/E31.113

(57) ABSTRACT

Photovoltaic (PV) crystalline silicon modules and methods of manufacturing wherein the modules contain a non-glass front sheet, upper and lower encapsulate layers, a PV cell layer, an insulating sheet, and a structural back plane comprising an aluminum composite. The front sheet can be comprised of ETFE, the encapsulate layers comprise EVA, and the back plane preferably comprises APA. This particular configuration results in a lightweight PV module that still retains a high power density, and can be readily installed onto rooftops without traditional heavy racking. The PV module may be adhered to the roof using a double sided pressure sensitive adhesive or heat welded.

### FIELD OF THE INVENTION

The teachings herein are directed to durable, light weight, crystalline silicon based photovoltaic modules having high power density that can be readily installed onto rooftops without traditional racking and methods of making the same.

### BACKGROUND

A photovoltaic module (also known as a “PV module” “solar panel” or “photovoltaic panel”) is an interconnected assembly of photovoltaic cells (also known as “PV cells” or “solar cells”) capable of converting photons from sunlight into usable electricity for commercial and residential applications. While widely used in construction, the weight of traditional PV modules has presented system designers, project managers, general contractors and solar integrators many challenges when designing and installing. Accordingly, there is an ever growing need for the implementation of light weight PV modules.

Prior attempts at lowering the weight of PV modules have focused on using non-crystalline, or thin film based PV technology. While non-crystalline silicone is lighter than crystalline silicone, it comparatively provides lower power density. More importantly is that the flexibility of thin film technologies allows non-rigid materials in construction—hence lighter weight. While high power density is advantageous on any rooftop application, it is especially important on commercial buildings due to their limited space and their high energy consumption during peak consumption times. An additional disadvantage of thin film solar panels is that they deteriorate faster than crystalline solar panels; accordingly their power output will fall more quickly over the course of use.

In addition to the weight of the module itself, traditional rack mounted PV modules typically require intricate and heavy support structures or roof warranty voiding penetrations in order to successfully mount them to a rooftop. As many rooftops lack the structural integrity to support the additional weight of these support structures, installing PV modules has been a costly and often impossible option for many buildings.

Accordingly, it is an object of the teachings herein to provide durable PV modules and that are light weight yet still retain a high power density and that can be readily installed onto rooftops without traditional racking or roof penetration.

### SUMMARY OF THE INVENTION

Embodiments herein are directed to photovoltaic (PV) crystalline silicon modules and methods of manufacturing. According to preferred embodiments, the PV modules herein include: a non-glass front sheet, a first upper encapsulate layer comprising ethylene vinyl acetate (EVA), a PV cell layer comprising a plurality of crystalline silicone cells operably coupled to circuitry, a first lower encapsulate layer comprising EVA, an insulating sheet, and a structural back plane comprising an aluminum composite.

Preferred methods are directed to arranging a PV module in the following layers: a non-glass front sheet, a first upper encapsulate layer comprising ethylene vinyl acetate (EVA), a PV cell layer comprising a plurality of crystalline silicone cells operably coupled to circuitry, a first lower encapsulate layer comprising EVA, an insulating sheet, and a structural back plane comprising an aluminum composite, and then laminating said layers inside a laminator, to create a PV module.

### BRIEF DESCRIPTION OF THE DRAWINGS

FIG. 1 is an exploded view of a PV module.

FIG. 2 is a planar view of a PV module.

FIG. 3 is a close up exploded view of a PV module.

FIG. 4 is a view of a right side diode cup.

FIG. 5 is a view of a left side diode cup.

FIG. 6 is a close up view of a PV module.

FIG. 7 is a close up view of a diode.

It will be appreciated that the drawings are not necessarily to scale, with emphasis instead being placed on illustrating the various aspects and features of embodiments of the invention.

### DETAILED DESCRIPTION OF THE ILLUSTRATED EMBODIMENTS

Embodiments of the present invention are described below. It is, however, expressly noted that the present invention is not limited to these embodiments, but rather the intention is that modifications that are apparent to the person skilled in the art and equivalents thereof are also included.

### PV Modules

The teachings herein are directed to novel crystalline silicon PV modules that are much lighter than traditional crystalline silicon PV modules, and as a result do not require the traditional racking for installation. According to preferred embodiments, PV modules that utilize non-crystalline or amorphous silicon are expressly excluded from the teachings herein. Crystalline silicon is widely known in the art and expressly includes both monocrystalline and multicrystalline embodiments. Over the last decade thin film technology has also gained limited acceptance mainly due to its flexible properties.

A conventional PV crystalline module typically consists of a tempered glass front sheet, a first layer of encapsulant (e.g., EVA), the layer of PV cells, a second layer of encapsulant, and an insulating backsheet (e.g., TPT). As one of the main objectives herein is to provide a lighter PV module, some of these materials were replaced or supplemented in order to reduce the weight of the PV modules herein.

According to preferred embodiments, a non-glass front sheet 21 can be used for the PV modules 100 herein in order to eliminate the weight of a typically used glass front sheet. Preferably Poly(ethylene-co-tetrafluoroethylene) (ETFE), a rugged material whose light transmission in the usable solar spectrum can be used as the front sheet 21. ETFE is part of a class of materials more commonly known as fluropolymers. Others from this class may be used instead of ETFE. Compared to glass, ETFE film is 1% of the weight, transmits more light and costs 24% to 70% less to install. ETFE has also been proven to withstand outdoor exposure to extreme weather conditions and the long term effect of UV exposure is well understood. Any suitable ETFE film 21 can be used with the teachings herein. In alternative embodiments, the PV module can utilize another material in the family of flouro-polymers as a top sheet replacement for the ETFE front sheet.

The use of ETFE as the front sheet 21 is known in the art, and is disclosed in U.S. Publication 2005/0178428 to Laaly et al., which is hereby expressly incorporated herein in its entirety. Preferably, the layer of ETFE 21 has a thickness ranging from 0.002-0.008 inches. Examples of suitable ETFE for use herein are ETFE matte finish film, made by Saint-Gobain Performance Plastics of Wayne, N.J., sold under the trademark NORTON®, ETFE film, ETFE made by E.I. Du Pont de Nemours sold under the trademark TEFZEL®, and ETFE film FLUON® available from AGC Solar.

According to preferred embodiments, it is desirable to maximize the amount of available sunlight passing through to the PV cells 110 for energy conversion. As processed ETFE is inherently smooth and will therefore reflect a certain amount of the sunlight, it can be advantageous to apply a texture onto the top surface of the ETFE 21, such as a Teflon woven cloth. This can be done during the lamination process described below, for example. Applied texture helps to scatter the incident light and reduce the total reflective losses of the PV module 100. According to certain embodiments, the top surface of the ETFE can also be stippled for safety or aesthetic reasons, for example. Accordingly, a mesh or screen made of suitable material or the like can be placed over top the ETFE layer to generate a screen pattern to be permanently embossed onto the top surface creating a textured surface. In alternative embodiments, the PV modules 100 herein forgo a textured surface, such as the use of a Teflon woven cloth.

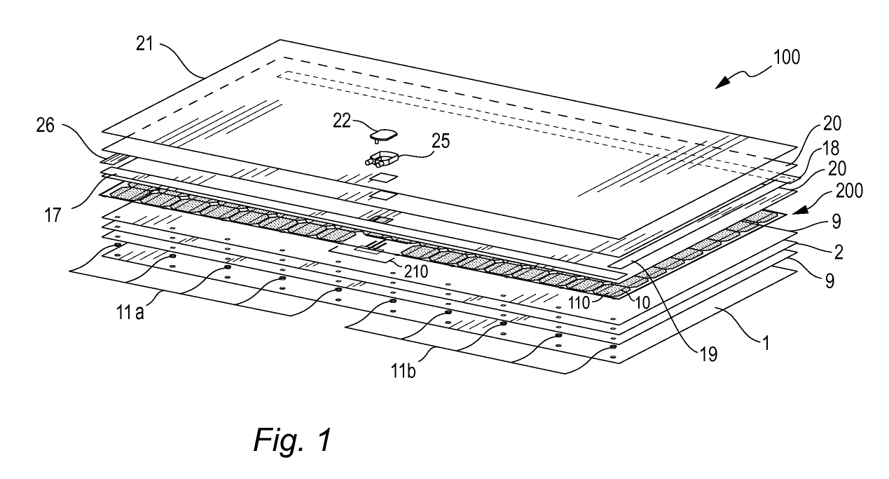

Preferred PV modules 100 herein can utilize multiple EVA layers to encapsulate the PV cell layer 200. Ethylene vinyl acetate (EVA) is a polymer that contains good clarity and loss barrier properties, low-temperature toughness, stress-crack resistance, water proof properties, and resistance to UV radiation. EVA is commonly used in the photovoltaic (PV) industry as an encapsulation material for silicon PV cells 110 in the manufacture of PV modules 100. As shown in FIG. 1 two upper EVA encapsulant layers 20 are placed between the front sheet 21 (e.g., ETFE) and the PV cell layer 200. Additionally another two lower EVA encapsulant layers 9 can be positioned below the PV cell layer 200. According to certain embodiments thin transparent layers of EVA 20 and 9 can be interposed as shown in FIG. 1. Alternatively a single upper EVA layer 20 and a single lower EVA layer 9 can be utilized. The method of applying EVA layers to glass based PV modules is well known in the art, and these methods can be used with the teachings herein to the degree they are applicable to the non-glass based modules provided herein. According to certain embodiments, the EVA used can contain additives for delaying its yellowing (which is caused by the exposure to the ultraviolet rays during the operating life of the solar panel) and be configured to prevent a direct contact between the PV cell layer 200 and the front sheet 21 and the back plane 1, to eliminate the interstices that would otherwise be formed because of a not perfectly smooth surface of the cells 110, and to electrically insulate the active part of the PV module 100.

The front sheet 21, upper EVA layers 20, and lower EVA layers 9 are added to the PV module 100, among other functions, to prevent “pin holing,” a phenomenon where the wiring 10 of the PV module 100 pierces a hole through the layers of the PV module 100 thereby detrimentally exposing the circuitry to the elements. Pin holing often results because the roofing surface is uneven and the PV module 100 consequentially warps.

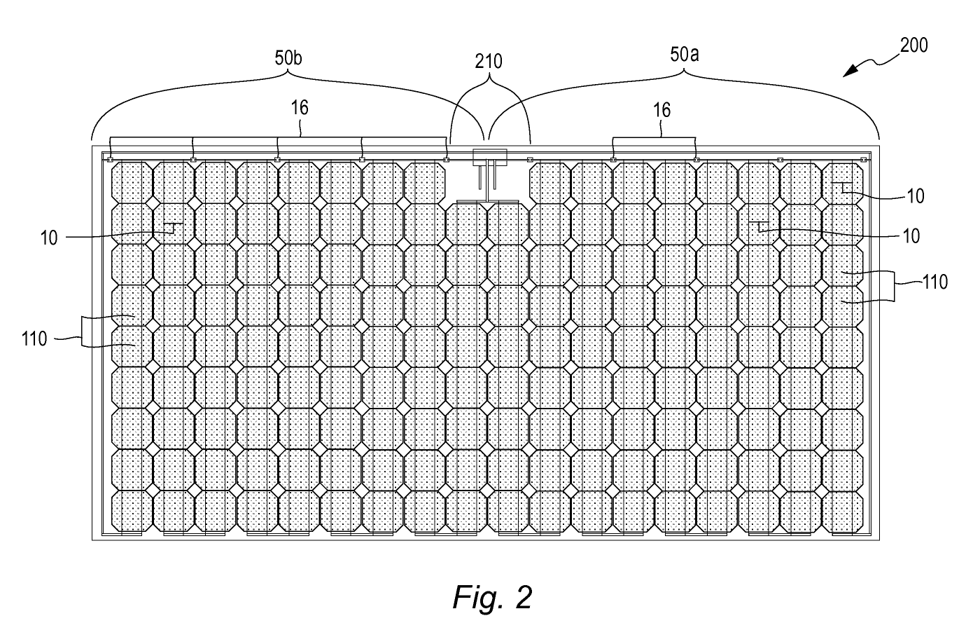

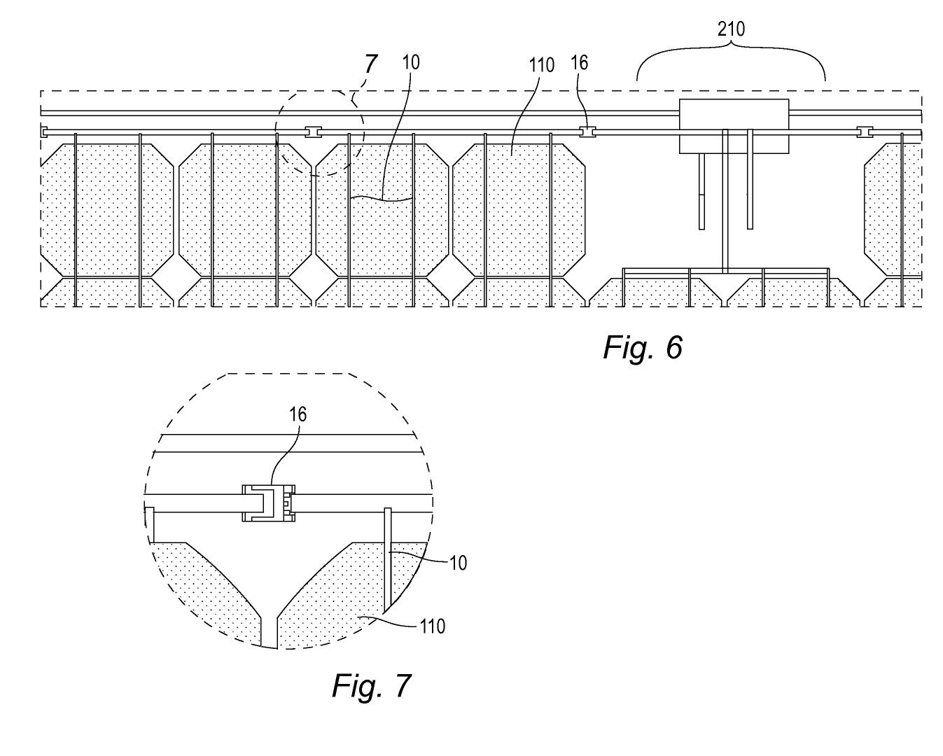

FIGS. 2 and 6 show a PV cell layer 200 advantageously comprising a plurality of crystalline silicone cells 110 operably coupled to circuitry (e.g., copper wiring) and to J box bussing 210. The J box bussing 210 generally serves as the interface between conductor ribbons of the PV cell layer 200 and DC input and output cables. In some embodiments, the J box bussing 210 contains bypass diodes to protect the PV module 100 from overheating during periods of mismatch, such as when the PV module 100 is in shade or covered by debris such as leaves.

As the PV modules 100 herein may be prone to thermal expansion that can negatively impact performance and reliability, preferred embodiments are directed to PV modules 100 having a in-plane geometric strain relief shape to help eliminate thermal expansion issues. More specifically, the cells 110 are preferably connected in cell strings, as this interconnections help prevent strain between the cells 110. Examples of this type of connection are provided in more detail in U.S. patent application Ser. No. 12/754,588 which is hereby expressly incorporated by reference in its entirety. A preferable design for the in-plane stress relief interconnects 10 is a length of 270 mm, width of 1.6 mm and thickness of 0.18 mm, and made of copper. These dimension are preferable because they allow for the easy and robust solder of the interconnects 10 to the PV cells 110, while simultaneously not unfavorably shading the PV cells which would reduce their efficiency. The preferred length of the interconnects is also optimal because it does not cause excessive performance degradation due to resistive loses. The length and shape of the interconnects 10 also allow for variable thermal expansion of the PV cells 110 as compared to the back plane 1. Because the back plane 1 will expand at a different rate than the PV cells 110 because they are made of different materials, the shape of the interconnect 110 (as shown in and incorporated from U.S. patent application Ser. No. 12/754,588) and the interconnect 110 dimensions allow it to compensate for the variable expansion within the plane of the PV cell layer 200 without causing breakage of the interconnect 10 or impingement by the interconnect 10 on the top ETFE sheet. Breakage and/or impingement of the interconnects 10 would reduce the durability and efficiency of the PV module 100. An additional advantage of this design is that it contains interconnects 10 in the same plane as the PV cell layer 200 which result in a smoother in-plane profile. This smoother profile further prevents/minimizes impingement of the top ETFE sheet caused by thermal expansion, enhancing durability of the product in the field and increasing its performance.

As shown in FIG. 2, a preferred PV cell layer 200 has a right-sided series 50b comprising a total of eighty cells 110 and a left-sided series 50a also comprising a total of eighty cells 110. More specifically, both the right-sided and left-sided series 50b and 50a individually comprise eight cell strings, each having nine crystalline silicon cells 110 and one cell string having eight crystalline silicon cells 110. Two parallel straight interconnects 10 can preferably run the length of a particular cell string.

According to preferred embodiments, the two cell series 50a and 50b are connected to each other in parallel to create a final PV cell layer 200 having a total of one hundred and sixty cells 110. The use of a parallel connection is advantageous in that it allows for the optimization of power production in the PV module 100. The specific number of cells in a cell string can be varied in further embodiments non-exclusively including: 4, 5, 6, 7, 8, 9, 10, 11, cells. Likewise, the number of cell strings in series can also vary, non-exclusively including: 1, 2, 3, 4, 5, and 6 series, for example. Final PV modules can include 2 series of 80 cells, 4 series of 40 cells, and 1 series of 160 cells, for example.

As shown in FIGS. 2, 6, and 7, diodes 16 can be soldered into place on the electrical circuitry of the PV cell layer 200 before laminating with the other layers of the PV module 100. According to more specific embodiments, the diodes 16 can be Schottky barrier bypass diodes 16, wherein ten diodes 16 are attached in a row on a single bussing wire configured to intersect the J Box bussing 210 (See FIG. 2). After being soldered, these diodes 16 can then be fixed during the lamination process described below. As most diodes 16 in prior art PV modules are attached separately from the lamination process, integrating diode 16 attachment during the lamination process simplifies the manufacturing applications provided herein.

According to preferred embodiments the PV modules 100 herein, utilize an aluminum composite, such as Aluminum-Polyethylene-Aluminum (APA) as a semi-rigid structural back plane 1. This material provides adequate support for the PV cell layer 200 while allowing some amount of flexure to conform to slight contours on a roof surface. An aluminum composite also helps to spread and maintain desired temperature profiles during the lamination process and thus allows for the correct cross linking of the encapsulant EVA layers 9 and 20. Similarly, this advantageous thermal behavior aids in the performance of the PV module 100, by dispersing the heat during non-uniform illumination. The aluminum composite back plane 1 also advantageously contributes to the overall lightweight of the PV module 100. Finally, a layer of aluminum composite 1 positioned as the outmost layer provides for an excellent surface for directly bonding the PV module 100 to the roofing material. Other non-exclusive examples of aluminum composites that can be used as the back plane 1 besides APA include Aluminum-Polypropylene-Aluminum, and Aluminum-Polycarbonate-Aluminum.

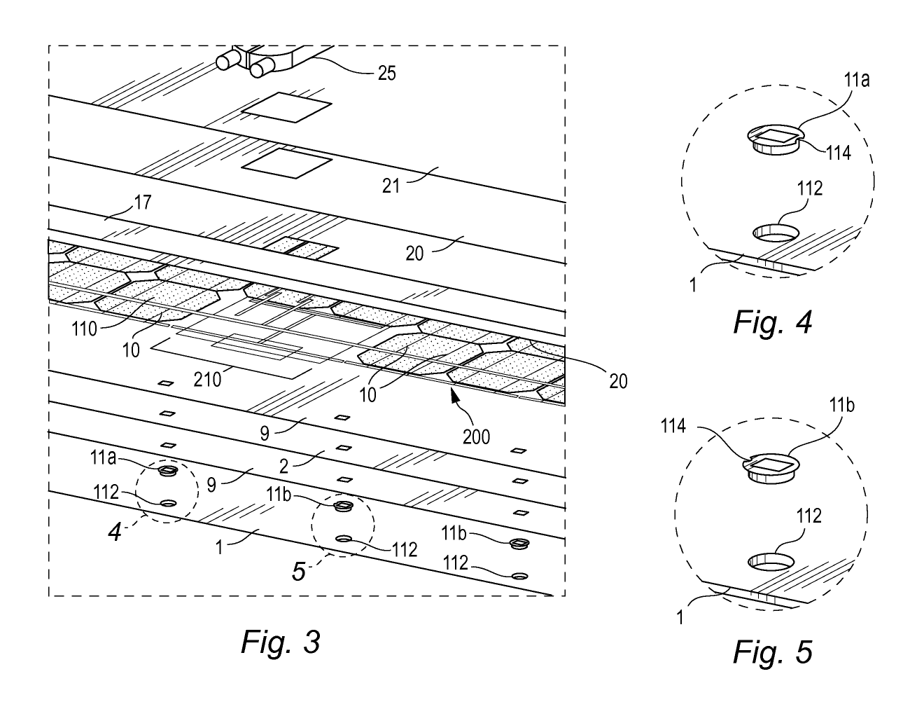

As shown in FIGS. 1 and 3-5, in order to insulate the diodes 16 from the aluminum composite back plane 1, isolating, plastic, or non-metal diode cups 11a and 11b can be used to house the diodes 16. According to advantageous embodiments, the aluminum back plane 1 can be lined with a plurality of holes 112, where each hole 112 is configured to receive a diode cup 11a and 11b. Accordingly the diodes 16, the diode cups 11a and 11b, and cup holes 112 are each aligned with each other during lamination. Right side diode cups 11a and the left side diode cups 11b can be distinguished from each other by the alignment of their grooves 14. More specifically, and as shown in FIG. 3, the right side diode cups 11a have grooves 14 on their left side facing the J box bussing 210, while the left side diode cups 11b have grooves 14 on their right side facing the J box bussing 210.

One disadvantage of the back plane 1 is that it is usually received having an upper and lower thin perimeter of aluminum which, if left untouched, would require grounding. As regulatory bodies require that exposed metal on a PV module 100 be grounded and it is generally known in the art that ground wiring is cumbersome, the upper and lower perimeters of aluminum formed on the back plane 1 can be removed prior to the lamination process, by any number of mechanical or chemical processes including scoring, peeling and machining. Thus, according to advantageous embodiments, the final back plane 1 does not include any exposed metal on the finished laminate and thus reduces time and cost when installing the PV modules 100 herein. An alternative way of preventing the exposure of metal on the laminated PV module 100 is to attach a plastic, or non-metal, U-channel around the edges of the PV module 100.

Alternative embodiments of the PV modules 100 herein include a layer of single ply roofing material, such as TPO, PVC, EPDM, or modified bitumen attached to the back surface of the back plane 1. The application of single ply roofing material to the back plane 1 could be completed as a supplemental step or during the lamination process. This layer could be used as a bonding or welding surface between the PV module 100 and the roof.

Still further embodiments of the PV modules 100 herein utilize a flexible material, attached to the underside of the back plane 1 which could be a roofing material or another material used in PV applications such (e.g., TDT™ and TEDLAR™, both readily available from Isovolta, Madico or other manufacturers). This additional material is preferably larger in size than the aluminum composite back plane and is configured to act as a flexible skirt around the perimeter. The additional material is also advantageous for covering the metal edge of the back plane 1, as well as improving the overall robustness of the PV module 100. Alternatively, the other layers of the PV module 100 could also be extended, such as the upper EVA layers 20, lower EVA layers 9, and the front sheet 21. These extension options could reduce the possibility of water being trapped under the PV module 100 during operation or maintenance.

In order to isolate the PV cell layer 200 from the aluminum back plane 1, an insulating sheet 2 can be placed between. More specifically, the insulating sheet 2 can be placed between the first and second lower layers of EVA encapsulant 9. Preferred insulating sheets can comprise TDT™ and TEDLAR®. Additionally, strips of insulating material can be incorporated around the perimeter of the PV module 100. As shown in FIG. 1, a front strip 17, right strip 26, back strip 18, and a left strip 19 can be positioned along the sides of the PV module 100, more preferably between the first and second upper EVA layers 20, to protect exposed bussing ensuring field reliability.

In preferred embodiments, in addition to the layers described above, the PV module 100 can include a J box 25 and J box cover 22. Generally, a J box 25 houses the J box bussing 210 while the J box cover 22 serves as a removable top cover of the housing of the J box 25, thereby facilitating protection of the J box 25 components, as well as easy repair or replacement of components in the event of damage or wear.

The PV modules 100 herein can be installed directly on top of most available commercial and residential roofs, non-exclusively including those having a low slope or flat roof. The PV Modules 100 can also be installed on high slopped roofs. More specifically, the underside of the aluminum composite back plane 1 can advantageously be installed on top of a roof's single ply membrane and still have the benefit of high power density (W/m2) due to their inherent conversion efficiency. More specifically, the PV modules 100 herein can be installed to any suitable layer of single ply roofing material. Examples of suitable single ply roofing material non-exclusively include modified bitumen, thermosets such as Ethylene Propylene Diene Monomer (EPDM) and Chlorosulfonated Polyethylene (CSPE), also known as “Hypalon,” and thermoplastics such as Thermoplastic Polyolefin (TPO), and Polyvinyl Chloride (PVC). The PV module 100 may be adhered to the roof using a double sided pressure sensitive adhesive or heat welded.

### Methods of Manufacturing

General steps of traditional PV module manufacturing can be utilized with the methods of manufacturing the novel PV modules 100 provided herein. For example, U.S. Publication No. 2010/0031998 to Aguglia and U.S. Publication No. 2005/0178428 to Laaly et al., both describe ways of laminating layers to create PV modules, and are expressly incorporated herein by reference in their entireties, to the degree consistent with the teachings herein.

Prior to lamination, it can be advantageous to assemble the PV circuitry of the PV cell layer 200, including the J Box bussing 210. More specifically, according to the methods herein, diodes 16 can be soldered into place on the electrical circuitry, before laminating the layers together. According to more specific embodiments, the diodes 16 can be Schottky barrier bypass diodes 16, wherein ten diodes 16 are attached in a row on a single bussing wire configured to intersect the J Box bussing 210. After being soldered, these diodes 16 can then be fixed during the lamination process described below. As most diodes 16 in prior art PV modules are attached separately from the lamination process, integrating diode 16 attachment during the lamination process simplifies the manufacturing applications provided herein.

Broadly speaking, the PV modules herein 100 can be produced by stacking the layers 21, 20, 20, 200, 9, 2, 9, and 1 and permanently attaching the various layers to form the PV module 100. Methods of making PV modules 100 can further involve adhesives as is known in the art. According to preferred methods, the PV cell layer 200 can be glued to the EVA sheets 9 and 20 and to the aluminum composite back plane 1 through a vacuum curing (polymerization) process carried out in an apparatus known as “laminator,” comprising an upper chamber and a lower chamber horizontally divided by an elastic membrane, such as a silicone rubber diaphragm. The lower chamber of the laminator can contain a heating plate configured to fluctuate or maintain an constant inner temperature. It will be appreciated that alternative laminators having two heater plates, one located in the upper portion and one located in the lower portion thereof, may also be used with the teachings herein. Another method called vacuum bagging can be used in which the layers are sealed in a bag and all the air is evacuated from the bag such that the temperature can be altered independently of the pressure setting, potentially improving process time.

A typical laminating cycle can begin by stacking the layers of the PV module 100 shown in FIG. 1 and comprising a front sheet 21 (e.g., ETFE), two layers of upper EVA encapsulant 20, a PV cell layer 200 comprising crystalline silicon PV cells 110, a first layer of lower EVA encapsulant 9, a layer of insulating sheet 2 (e.g., TPT and TEDLAR®) a second layer of lower EVA encapsulant 9, and the aluminum composite back plane 1 (e.g., APA) inside the lower chamber of the laminator. As described above, alternative embodiments can also include only stacking a single layer of upper EVA encapsulant 20 and a single layer of lower EVA encapsulant 9. Once the layers are arranged in the laminator, a vacuum can be created in both chambers and the temperature in the laminator can be raised to a high temperature so as to remove air stagnation (bubbles) from the layers. The vacuum can then be removed from the upper chamber, so that the membrane separating the two chambers uniformly compresses the module thus favoring the adhesion of the layers and allowing the polymerization of the EVA layers 20 and 9. This step can typically last from 10 to 20 minutes, for example. Finally the temperature is lowered and air can be slowly admitted. Once the system is at approximately room temperature, finishing steps can be applied to the PV module 100. Finishing steps can non-exclusively include trimming any excess material from the PV module 100 and performing quality control testing on the PV module 100. According to advantageous embodiments, the parameters of the lamination cycle can be selected based on one or more of the following factors: the specifications supplied by the EVA manufacturers, the specific experimentation of the module producers, and an optimization of the process times with the aim to increase the production per hour.

To assess the strength of the PV modules, the solar panel industry incorporates a blade test. This test utilizes a blade with a 2 lbs weight on it, which is slid across the PV module. If the PV module survives the weight of the blade, it passes the test. With the ETFE/EVA layers of the present invention, certification tests have demonstrated that the blade can be loaded with an ample margin over the 2 lbs weight without PV module performance degradation.

While particular preferred and alternative embodiments of the present invention have been disclosed, it will be appreciated that many various modifications and extensions of the above described technology may be implemented using the teaching of this patent application. All such modifications and extensions are intended to be included within the true spirit and scope of this patent application

What is claimed is:

1. A photovoltaic (PV) crystalline silicon module comprising:
a non-glass front sheet;
a first upper encapsulate layer comprising ethylene vinyl acetate (EVA);
a PV cell layer comprising a plurality of crystalline silicone cells operably coupled to circuitry;
a first lower encapsulate layer comprising EVA;
an insulating sheet; and
a structural back plane comprising an aluminum composite.

2. The PV module of claim 1, wherein said front sheet comprises a fluropolymer.

3. The PV module of claim 2, wherein the surface of the front sheet is textured with a teflon woven cloth such as to scatter incident light and reduce reflective losses.

4. The PV module of claim 1, further comprises a second upper encapsulate layer comprising EVA, positioned between said first upper encapsulate layer and said PV cell layer and a second lower encapsulate layer comprising EVA positioned between said insulating sheet and the structural back plane.

5. The PV module of claim 1, wherein said aluminum composite is Aluminum-Polyethylene-Aluminum (APA).

6. The PV module of claim 1, wherein said insulating sheet comprises TEDLAR®.

7. The PV module of claim 1, wherein the PV cell layer comprises 2 or more series connected in parallel wherein each series comprises a plurality of cell strings.

8. The PV module of claim 1, further comprising an interconnect that electrically connects the plurality of crystalline silicone cells; wherein the PV cell layer defines a plane and the interconnect is in the same plane as the PV cell layer.

9. The PV module of claim 8, further comprising bussing that electrically connects to the interconnect, and comprising a strip that covers the bussing to prevents perforation between the layers.

10. The PV module of claim 8, wherein the structural back plane is made of a material with a coefficient of thermal expansion that is different than the coefficient of thermal expansion of the crystalline silicone cells, and the interconnect is configured to accommodate thermal stresses within the plane while maintaining its electrical connection with the plurality of crystalline silicone cells.

11. The PV module of claim 7, wherein said PV cell layer comprises a first and second series of eighty PV cells connected in parallel to create a full PV cell layer of 160 total cells.

12. The PV module of claim 1, wherein the PV cell layer further comprises Schottky barrier bypass diodes soldered onto the circuitry.

13. The PV module of claim 12, further comprising a plurality of isolative cups aligned with and configured to house said Schottky barrier bypass diodes.

14. The PV module of claim 1, wherein said back plane is configured to be directly adhered to a single ply roofing material without the use of additional racking.

15. The PV module of claim 1, wherein the backside of the back plane further comprises a single layer of single ply roofing material.

16. The PV module of claim 15, wherein said single ply roofing material is selected from the group consisting of: TPO, PVC, EPDM and modified bitumen.

17. A method of manufacturing a PV module comprising:
arranging a PV module in the following layers:
a non-glass front sheet;
a first upper encapsulate layer comprising ethylene vinyl acetate (EVA);
a PV cell layer comprising a plurality of crystalline silicone cells operably coupled to circuitry;
first lower encapsulate layer comprising EVA;
an insulating sheet; and
a structural back plane comprising an aluminum composite, and
laminating said layers inside a laminator, to create a PV module.

18. The method of claim 17, wherein a plurality of diodes are soldered onto the PV cell circuitry prior to lamination.

19. The method of claim 18, wherein said backplane comprises holes configured to receive diode cups configured to house and isolate the diodes from the back plane.

20. The method of claim 17, wherein the PV cell layer comprises 2 or more series connected in parallel wherein each series comprises a plurality of cell strings.

21. The method of claim 17, further comprising a second upper encapsulate layer comprising EVA and a second lower encapsulate layer comprising EVA.
